(19) United States
(12) Patent Application Publication
(10) Pub. No.: US 2015/0085902 A1
(43) Pub. Date: Mar. 26, 2015

(54) RFDAC Transmitter Using Multiphase Image Select FIR DAC and Delta Sigma Modulator with Multiple Rx Band NTF Zeros

(71) Applicant: QUALCOMM INCORPORATED, San Diego, CA (US)

(72) Inventors: Daniel Keyes Butterfield, Encinitas, CA (US); Sumit Verma, San Diego, CA (US); Jeremy Darren Dunworth, San Diego, CA (US); Bo Sun, Carlsbad, CA (US)

(73) Assignee: QUALCOMM INCORPORATED, San Diego, CA (US)

(21) Appl. No.: 14/034,243

(22) Filed: Sep. 23, 2013

(51) Int. Cl. H03M 1/12; H04B 1/38

(52) U.S. Cl. CPC H03M 1/1245; H04B 1/38
USPC 375/219

(57) ABSTRACT

A transmitter includes a delta-sigma modulator characterized by a noise transfer function having a multitude of zeroes positioned substantially near a frequency band of a receive signal. The transmitter further includes, in part, a multi-phase digital-to-analog (DAC) converter converting an output signal of the delta-sigma modulator to an analog signal. The DAC is characterized by a transfer function that passes the desired signal to its output and attenuates a multitude of images of the sampling clock signal. The transmitter transmits at a frequency defined by an odd multiple of a fraction of the sampling clock signal frequency. The DAC includes a number of stages each pair of which is associated with one of the images being attenuated. The delta-sigma modulator includes a multitude of stages each associated with a different one of the zeroes. Each stage of said delta-sigma modulator optionally receives three tap coefficients.

### BACKGROUND

The present disclosure relates to electronic circuits, and more particularly to a transmitter used in such circuits.

A wireless communication device, such as a cellular phone, includes a transmitter for transmitting signals and a receiver for receiving signals. The receiver often downconverts an analog radio frequency (RF) signal to an analog baseband signal or analog intermediate frequency (IF) signal which is filtered, amplified, and converted to a digital baseband signal in an analog to digital converter (ADC). Likewise, the transmitter converts a baseband digital signal to an analog signal, which is filtered and upconverted to an RF signal before being transmitted. In many wireless communication devices one or more receivers and one or more transmitters operate concurrently on different frequency bands. This means that the transmitters must control their spurious emissions into the receive bands so as not to degrade the performance of the concurrently operating receivers. The transmit spurious emissions into the receive band of a concurrently operating receiver can be called receive band noise.

In a transmitter, the receive band noise and transmit signal linearity need to be concurrently met while maintaining optimal power consumption and increasingly wider signal bandwidth. As transceiver design moves to smaller geometries and processing nodes, the relatively high cost of integrating such components as baseband digital-to-analog converters (DAC), analog filters, upconverters, and the like, on the same semiconductor substrate is posing a challenge. Furthermore, the images (also referred to as aliases or harmonics) associated with Nyquist sampling of the transmit signal, as well as the quantization noise in concurrently operated receive bands need to be properly handled in order to meet emission requirements and receiver sensitivity.

### BRIEF SUMMARY

A communication device, in accordance with one embodiment of the present invention, includes a transmitter that in turn includes, in part, a delta-sigma modulator receiving an RF signal and characterized by a noise transfer function having a multitude of zeroes positioned substantially near frequency bands of a concurrently received signals, and a multi-phase digital-to-analog (DAC) converter configured to convert the output signal of the delta-sigma modulator to an analog signal. The DAC is characterized by a transfer function that passes a selected desired Nyquist image of a sampled signal to its output (i.e., the desired signal), while attenuating a multitude of the undesired images of the sampled signal.

In one embodiment, the communication device further includes, in part, a digital modulator configured to upconvert the transmit signal from a baseband frequency signal to the RF signal. In one embodiment, the RF signal received by the delta-sigma modulator is a digital RF signal.

In one embodiment, the DAC includes a multitude of stages each of which is associated with a gain coefficient (tap weight) of a finite impulse response filter (FIR). In one embodiment, the communication device is configured to transmit at a frequency defined by an odd multiple of a fraction of the sampling frequency. In one embodiment, the communication device is configured to transmit at odd multiples of one-fourth of the sampling frequency.

In one embodiment, the baseband signal includes an in-band signal component and a quadrature-phase signal component. In one embodiment, the DAC attenuates the third, fifth, and seventh harmonics of the sampled signal. In one embodiment, the DAC is a current steering DAC each stage of which includes a current source providing a current whose value is defined by a tap weight associated with that stage.

In one embodiment, the fraction of the sampling frequency used to transmit the signal defines the number of phases of the sampling clock signal received by the DAC. In one embodiment, the DAC's output is applied to a load, the output of which is applied to an amplifier. In one embodiment, the delta-sigma modulator includes a multitude of stages each of which comprises a forward path section and a feedback path section. The forward path section is associated with a different one of the zeroes and the feedback path section is associated, along with the feedback path sections of the rest of the stages, with the poles of the signal and noise transfer functions. In one embodiment, each stage of the delta-sigma modulator receives up to three tap coefficients.

In one embodiment, the communication device further includes a receiver configured to receive at a frequency defined by an odd multiple of a fraction of the sampling clock signal frequency. In one embodiment, the fraction is ¼. In one embodiment, the communication device further includes, in part, a local oscillator shared by the transmitter and the receiver. The shared LO has a frequency that is a multiple of the receive frequency. In one embodiment, the subset of the plurality of images being attenuated is defined by odd multiples of a fraction of the sampling clock signal frequency. In one embodiment, such fraction is defined by a ratio of the transmit frequency to the receive frequency.

A method of wireless communication, in accordance with one embodiment of the present invention, includes, in part, modulating an RF signal to generate a multitude of zeroes positioned substantially near the frequency band of a receive signal or a multitude of frequency bands of concurrently received signals, attenuating a multitude of odd-harmonically spaced Nyquist images of a sampled signal, converting the modulated RF signal to an analog signal, and transmitting the analog signal.

In one embodiment, the method further includes upconverting a baseband signal to generate the RF signal, which may be a digital RF signal. In one embodiment, the RF signal is transmitted at a frequency defined by an odd multiple of a fraction of the sampling clock signal frequency. In one embodiment, the RF signal is transmitted at a frequency defined by an odd multiple of one-fourth of the sampling clock signal frequency.

In one embodiment, the modulated RF signal is converted to the analog signal using a current steering DAC. In one embodiment, the current steering DAC includes a number of stages that is one higher than twice the number of the undesired Nyquist images of the sampled signal being attenuated. In one embodiment, each stage of the current steering DAC includes a current source providing a current whose value is defined by a tap weight associated with that stage.

In one embodiment, the fraction of the sampling frequency used to transmit the signal defines the number of phases of the sampling clock signal received by the DAC. In one embodiment, the method further includes applying the output of the DAC to a load, and applying the output of the load to an amplifier. In one embodiment, the method further includes modulating the RF signal via a multitude of stages each of which is associated with a different one of the zeroes. In one embodiment, the method further includes applying up to three tap coefficients to each of the stages.

In one embodiment, the method further includes, in part, receiving a second RF signal at a frequency defined by an odd multiple of a fraction of a sampling clock signal frequency used to sample the baseband transmit signal. In one embodiment, the fraction is ¼. In one embodiment, the method further includes sharing a local oscillator between a transmitter transmitting the RF signal and a receiver receiving the second RF signal. In one embodiment, the shared LO has a frequency that is a multiple of the receive frequency. In one embodiment, the subset of the plurality of images being attenuated is defined by odd multiples of a fraction of the sampling clock signal frequency. In one embodiment, such a fraction is defined by a ratio of the transmit frequency to the receive frequency.

### BRIEF DESCRIPTION OF THE DRAWINGS

Aspects of the disclosure are illustrated by way of example. In the accompanying figures, like reference numbers indicate similar elements, and:

FIG. 1 is a block diagram of a wireless communication device, in accordance with one embodiment of the present invention.

FIG. 2 is a block diagram of a Delta-Sigma modulator disposed in the wireless communication device of FIG. 1, in accordance with one embodiment of the present invention.

FIG. 3 shows the noise spectrum of the Delta-Sigma modulator of FIG. 2 when configured to having zero pairs at select receiver frequency bands, in accordance with one embodiment of the present invention.

FIG. 4 is a block diagram of a finite impulse response (FIR) digital-to-analog (DAC) converter, disposed in the wireless communication device of FIG. 1, in accordance with one embodiment of the present invention.

FIG. 5 is a simplified schematic diagram of one of the stages of the FIR DAC of FIG. 4, in accordance with one embodiment of the present invention.

FIG. 6A is the signal transfer function of the FIR DAC of FIG. 5 when configured to suppress the 3^{rd}, 5^{th} and 7^{th} harmonics of the sampled signal, in accordance with one embodiment of the present invention.

FIG. 6B shows the relationship between phases φ₁, φ₂, φ₃, φ₄ of the clock signals applied to various delay stages of the FIR DAC of FIG. 5 when configured to suppress the 3^{rd}, 5^{th} and 7^{th} harmonics of the sampled signal, in accordance with one embodiment of the present invention.

FIG. 7A is the signal transfer function of the FIR DAC of FIG. 5 when configured to suppress the 1st, 5^{th} and 7^{th} harmonics of the sampled signal, in accordance with one embodiment of the present invention.

FIG. 7B shows the relationship between phases φ₁, φ₂, φ₃, φ₄ of the clock signals applied to various delay stages of the FIR DAC of FIG. 5 when configured to suppress the 1^{st}, 5^{th} and 7^{th} harmonics of the sampled signal, in accordance with one embodiment of the present invention.

FIG. 8 is a block diagram of a wireless communication device where local oscillator can be shared by the transmitter and the receiver, in accordance with one embodiment of the present invention

FIG. 9 shows a flowchart for transmitting an RF signal, in accordance with one embodiment of the present invention.

FIG. 10 is a block diagram of another finite impulse response (FIR) digital-to-analog (DAC) converter, disposed in the wireless communication device of FIG. 1, in accordance with one embodiment of the present invention.

FIG. 11 shows a block diagram of a combined Fs/4 and 3Fₛ/4 mode clock phase generator and 1^{st} tap data generator, in accordance with one embodiment of the present invention.

FIG. 12 shows the relationship between fs2x, fs2xb, φₐ, φ_{b}, and phases φ₁ and φ₂ of the clock signals applied to various delay stages of the FIR DAC of FIG. 10, in accordance with one embodiment of the present invention.

FIG. 13 shows tap clock and data path of a register delay block, in accordance with one embodiment of the present disclosure.

### DETAILED DESCRIPTION

Several illustrative embodiments will now be described with respect to the accompanying drawings, which form a part hereof. While particular embodiments, in which one or more aspects of the disclosure may be implemented, are described below, other embodiments may be used and various modifications may be made without departing from the scope of the disclosure.

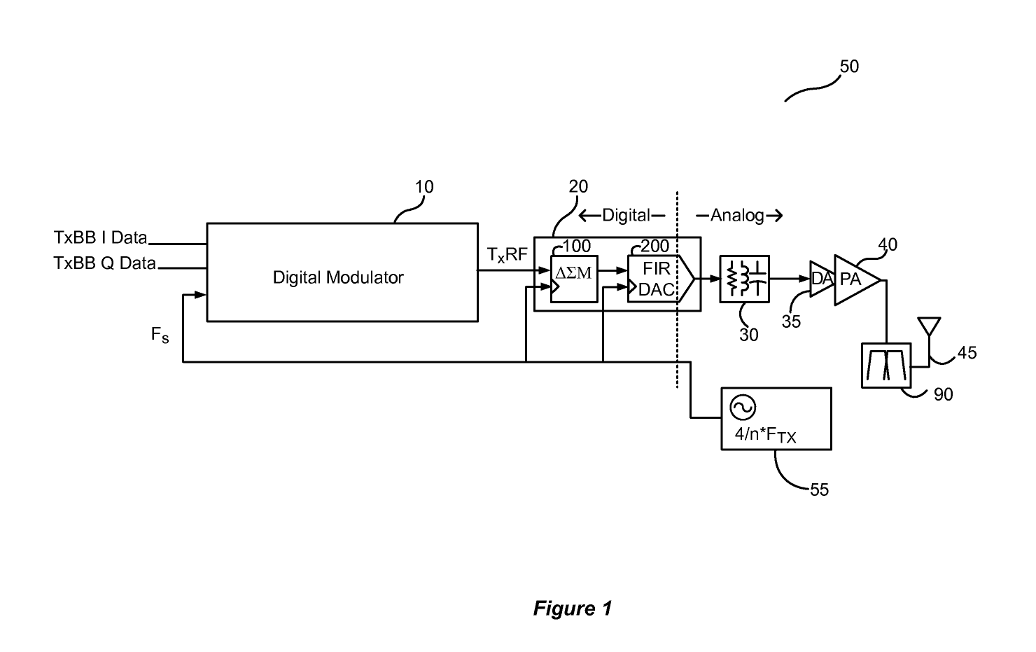

FIG. 1 is a simplified block diagram of a wireless communication device 50, in accordance with one embodiment of the present invention. Device 50 may be a cellular phone, a personal digital assistant (PDA), a modem, a handheld device, a laptop computer, and the like. Device 50 may communicate with one or more base stations on the downlink (DL) and/or uplink (UL) at any given time. The downlink (or forward link) refers to the communication link from a base station to the device. The uplink (or reverse link) refers to the communication link from the device to the base station.

Device 50 may be a multiple-access system capable of supporting communication with multiple users by sharing the available system resources (e.g., bandwidth and transmit power). Examples of such systems include code division multiple access (CDMA) systems, wide-band CDMA (WCDMA), frequency division duplex long term evolution (LTE), time division multiple access (TDMA) systems, frequency division multiple access (FDMA) systems, orthogonal frequency division multiple access (OFDMA) systems, spatial division multiple access (SDMA) systems, and the like.

Device 50 is shown as including, in part, digital modulator 10, DAC 20, load 30, antenna 45, and oscillator 55. Device 50 is also shown as including optional drive amplifier 35 and power-amplifier 40 and RF filter 90. Oscillator 55 is configured to generate a sampling clock signal Fₛ whose frequency is defined by the frequency of the transmit clock signal F_{TX}. The following description of device 50 is made with reference to a sampling clock signal Fₛ having a frequency that is (4/n) times the frequency of the transmit clock signal F_{TX}, where n is an odd integer ranging from 1 to 7 corresponding to the harmonics of the Nyquist images of the sampled signal T_{X}RF being attenuated. It is understood, however, that embodiments of the present invention apply to any other relationship between clock signals Fₛ and F_{TX}. It is also understood that in other embodiments of the present invention n may be any other odd integer, such as 9, 11, etc.

Digital modulator 10 is configured to upconvert the I/Q baseband transmit signals TxBB_I and TXBB_Q to an upsampled digital RF signal TxRF which is delivered to DAC 20. DAC 20 is shown as including a Delta-Sigma modulator 100 and a multi-phase harmonic attenuator 200, also referred to herein as Finite Impulse Response (FIR) DAC. As described in detail below, Delta-Sigma modulator 100 is configured to attenuate the noise generated by the transmitter at the frequencies where the received signal is present. As is also described in detail below, DAC 200 is configured to attenuate the odd-harmonically spaced Nyquist images (also referred to herein as images or aliases) generated as a result of the sampling operation performed by digital modulator 10. In response to the output signal of Delta-Sigma modulator 100, DAC 200 drives a passive load 30 that may be an LC tank resonating at the RF frequency. The LC tank may be formed by connecting one or more inductors in parallel with one or more capacitors. The output of load 30 is applied to antenna 45 via optional driver amplifier (DA) 30 and optional power amplifier (PA) 40 and optional RF Filter 90. In common applications RF Filter 50 may be a surface acoustic wave (SAW) filter or a duplexer.

Delta-Sigma modulator 100 is adapted to generate quantization noise transfer function zero pairs at frequencies substantially near the concurrently operating receive frequency bands. Delta-Sigma modulator 20 has a z-domain quantization noise transfer function H_{NTF}(z) defined as follows:

$${H}_{NTF} ( z ) = {\prod }_{K = 1}^{N / 2} \frac{1 - 2 cos 2 π \frac{{f}_{Rxk}}{{F}_{S}} {z}^{- 1} + {z}^{- 2}}{1 - 2 {r}_{k} cos {ϕ}_{k} {z}^{- 1} + {r}_{k}^{2} {z}^{- 2}} \qquad ( 1 )$$

In the above expression (1), Fₛ represents the sampling frequency used by digital modulator 10, rₖ represents the pole magnitudes, φₖ represents the angular frequency of poles geometrically distributed around π/2, f_{Rxk} represents the multiple receive frequency bands with k being an index varying from 1 to N/2, and N represents the number of zero pairs being generated at the receive frequency bands. In one example, rₖ may vary from 0.25 to 0.5. As described above, the quantization noise transfer function H_{NTF}(z) is selected to have zero pairs at frequencies substantially near the concurrently operating receive frequency bands.

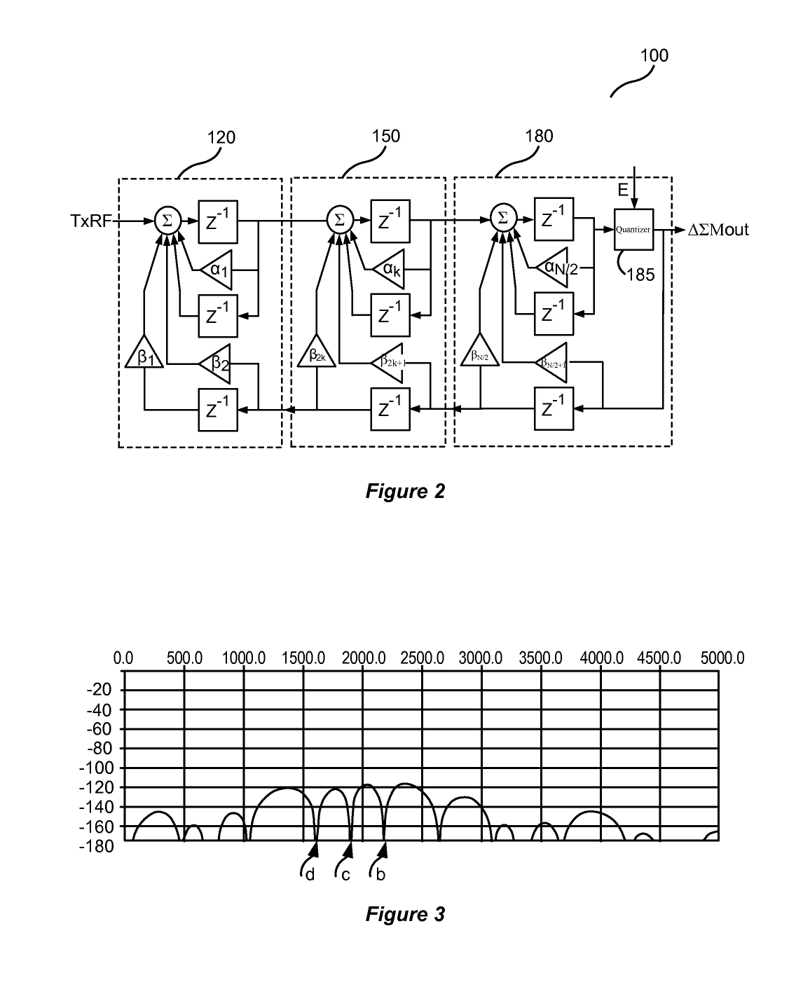

FIG. 2 is an exemplary block diagram of a Delta-Sigma modulator with an H_{NTF}(z) characterized by expression (1), and in which N is 6. The Delta-Sigma modulator is shown as including 3 stages 120, 150 and 180, each of which is a second order stage adapted to generate a pair of zeros. Consequently, the Delta-Sigma modulator shown in FIG. 2 is adapted to generate 3 pairs of zeros at frequencies substantially near the concurrently operating receive frequency band. As is well known, each z⁻¹ block represents a delay stage implemented by a register. Quantizer block 185 receives the output of stage 180 and quantizes output to the desired bit-width. Quantizer block 185 can be modeled as a summation block that receives the output of stage 180 as well as the quantization noise E. It is understood that H_{NTF}(z) represents the transfer function of the noise source generating the quantization noise E created by quantization block 185. In an embodiment quantization block 185 could take a 16-bit input and quantize it to 4 bits.

Tap filter values are set in accordance with coefficients α, β₁ and β₂. Coefficients α are selected to define the zero pairs of the noise transfer function at multiple receive band frequencies f_{Rxk} and may be computed in accordance with the expression below:

$${α}_{k} = - 2 cos 2 π \frac{{f}_{Rxk}}{{F}_{S}}$$

Coefficients β₁ and β₂ are selected to define the poles of the noise transfer function and thus determine the stability of the Delta-Sigma modulator. An algorithm for determining β₁ and β₂ of stage 120 is shown below. It is understood that a similar algorithm may be used to determine coefficients β₁ and β₂ of the stages 150, 180, as well as similar coefficients of any higher order stage (not shown) of a Delta-Sigma modulator. For stage 120, k is 1, therefore:

$${α}_{1} = - 2 cos 2 π \frac{{f}_{Rx 1}}{{F}_{S}} \\ {H}_{NTF} ( z ) = \frac{1 - {α}_{1} {z}^{- 1} + {z}^{- 2}}{1 - 2 {r}_{1} cos {ϕ}_{1} {z}^{- 1} + {r}_{1}^{2} {z}^{- 2}} \qquad ( 2 )$$

Using well known rules for deriving transfer functions from their associated signal flow graphs, it is seen that H_{SFG} may be defined as follows:

$$\begin{matrix}{H}_{SFG} = \frac{Δ \sum Mout}{E} \\ = \frac{1}{1 - {B}_{2} \frac{{z}^{- 1}}{1 - {α}_{1} {z}^{- 1} + {z}^{- 2}} - {β}_{1} {z}^{- 1} \frac{{z}^{- 1}}{1 - {α}_{1} {z}^{- 1} + {z}^{- 2}}}\end{matrix}$$

The above expression may further be simplified as:

$$\begin{matrix}{H}_{SFG} = \frac{1 - {α}_{1} {z}^{- 1} + {z}^{- 2}}{( 1 - {α}_{1} {z}^{- 1} + {z}^{- 2} ) - {β}_{2} {z}^{- 1} - {β}_{1} {z}^{- 2}} \\ = \frac{1 - {α}_{1} {z}^{- 1} + {z}^{- 2}}{( 1 - {α}_{1} + {β}_{2} ) {z}^{- 1} + ( 1 - {β}_{2} ) {z}^{- 2}}\end{matrix} \qquad ( 3 )$$

Given that the numerators of expression (2) and (3) are equal, solving for coefficients β₁ and β₂ results in the following:

β₁=1−r₁²

β₂=2rₖ cos φₖ−α₁

The Delta-Sigma modulators in FIGS. 1 and 2 are shown as being 16-bits wide and having 4-bit outputs. It is understood however, that a Delta-Sigma modulator, in accordance with the present invention, may have an output that has fewer or more than 4 bits. The bit-width of the Delta-Sigma modulator defines the number of quantization levels and corresponding quantization noise power spectral density (PSD), in turn affecting the peak noise PSD outside the receive band spectrum. As a consequence of this peak noise PSD, the bit-width of the Delta-Sigma modulator is also defined, in part, by the transmitter spectral emission requirements with which device 50 is required to comply. FIG. 3 shows the noise spectrum of the Delta-Sigma modulator of FIG. 2 when configured to have 2 zero pairs at receiver frequencies 2170 MHz (identified as point b), 2 zero pairs in the receiver frequency band 1810-1875 MHz (identified as point c), and 2 zero pairs at receive frequency 1575 MHz (identified as point d).

FIR DAC 200 is adapted to suppress a number of Nyquist images of the sampled signal TxRF. For example, if the transmit frequency of TxRF is ¼ of Fₛ, FIR DAC 200 may be configured to eliminate the 3^{rd}, 5^{th} and 7^{th} odd-harmonically spaced images of TxRF. Likewise, if the transmit frequency is ¾ of Fₛ, FIR DAC 200 may be configured to eliminate, the 1^{st}, 5^{th} and 7^{th} images. It is understood that in other embodiments multiple integers of a fraction other than ¼ of the sampling clock Fₛ frequency may be used for transmission.

The following description is made with reference to a FIR DAC configured to suppress 3 of the images of the TxRF. It is understood however that, in accordance with the present invention, any number of images of the TxRF, such as four (e.g., 3^{rd}, 5^{th}, 7^{th} and 9^{th} harmonics) may be suppressed. It is further assumed below that the transmit signal TxRF has a frequency F_{Tx} that is (n*¼) of the sampling clock Fₛ frequency, where n is a member of the set {1, 3, 5, 7}. To achieve this, the FIR DAC is configured to have a signal transfer function that has a defined gain at the desired frequency-representative of a desired image at multiple Fₛ/4 frequencies indexed by any one of {1, 3, 5, 7}—and a zero at each of the undesired harmonics to be suppressed—representing undesired images indexed by {α1, α2, α3} where α1, α2, α3 may take on any of the values of {1, 3, 5, 7} except for the value selected for n. For example, if the desired image, i.e., n is selected to be the first harmonic, α1, α2, α3 may have values of 3, 5, 7 representing the undesired harmonics. To suppress three of the harmonics of signal Fₛ, the FIR DAC is selected to have 7 taps.

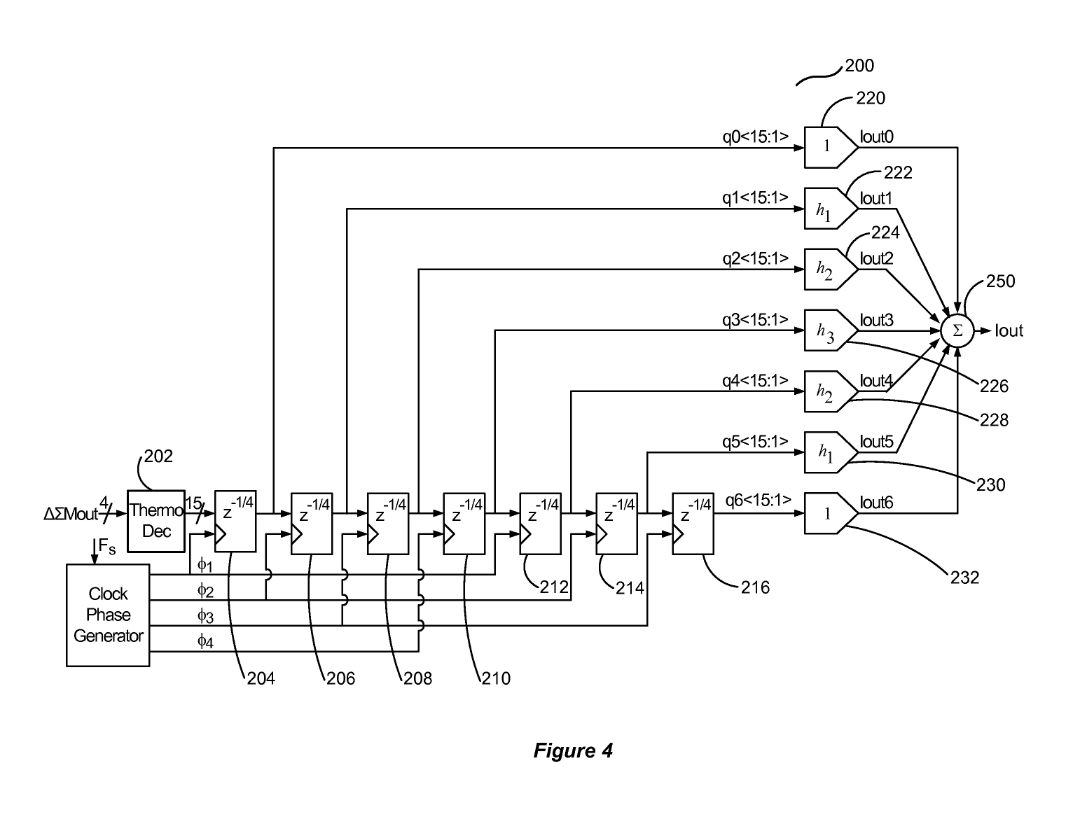

FIG. 4 is a schematic block diagram of a 7-tap, 16-level FIR DAC 200 (e.g., first embodiment) in accordance with one exemplary embodiment of the present invention. FIR DAC 200 is shown as including a thermo decoder 202 receiving the output signal of the Delta-Sigma modulator, and 7 delay stages 204, 206, 208, 210, 212, 214, 216. The outputs of the delay stages are shown as being applied to current steering DAC stages 220, 222, 224, 226, 228, 230, 232 which respectively receive tap weights of 1, h₁, h₂, h₃, h₂, h₁, and 1. The currents generated by the 7 stages, namely currents Iₒᵤₜ₀, Iₒᵤₜ₁, Iₒᵤₜ₂, Iₒᵤₜ₃, Iₒᵤₜ₄, Iₒᵤₜ₅ and Iₒᵤₜ₆ are summed by summing network 250 and subsequently converted to an analog voltage forming the output of FIR DAC 200. As DAC stages 220, 222, 224, 226, 228, 230 and 232 can be current steering DAC stages, summing network 250 can be as simple as a pair of wires connecting the differential DAC stage outputs.

Thermo decoder 202 is well known and is adapted to convert the 4-bit output of the Delta-Sigma modulator to 15-bit data corresponding to 16 distinct DAC output levels that are delivered to each of the delay stages 204, 206, 208, 210, 212, 214, 216 (z^{-1/4}) each of which is shown as including a register having a clock signal that receives a different one of four different clock phases φ₁, φ₂, φ₃, φ₄. As described above, the output of each delay stage is received by an associated DAC stage. For example, the output of delay stage 204 is received by associated DAC stage 220. Likewise, the output of delay stage 208 is received by associated DAC stage 224; and the output of delay stag 216 is received by associated DAC stage 232.

Each of DAC stages 220, 222, 224, 226, 228, 230, 233 is adapted to generate a current defined by the data it receives from its associated delay stage and its selected tap weight. For example, the output of DAC stage 220 is defined by the 15-bit data it receives from its associated delay stage 204 and its tap weight which is selected to be 1. Likewise the output of DAC stage 222 is defined by the 15-bit data it receives from its associated delay stage 206 and its selected tap weight h₁; and the output of DAC stage 224 is defined by the 15-bit data it receives from its associated delay stage 208 and its selected tap weight h₂.

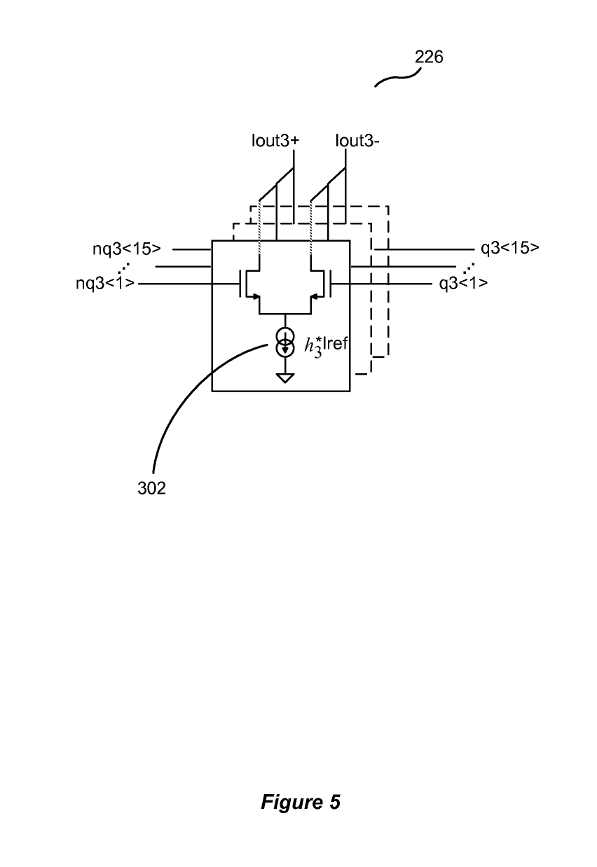

FIG. 5 is a simplified schematic diagram of DAC stage 226. DAC stage 226 is shown as including 15 parallel input stages each receiving a different one of differential data bits q3<n>, nq3<n> (n is an integer varying from 1 to 15 in this exemplary embodiment) and generating a pair of differential currents Iₒᵤₜ₃⁺ and Iₒᵤₜ₃⁻ in response. The current source 302 disposed in DAC stage 226 has a value defined by h₃*I_{ref}, where I_{ref} is a reference current and h₃ is the tap weight selected for stage 226. While not shown, it is understood that each of the remaining DAC stages 220, 222, 224, 228, 230, 232 has a current source defined by a product of I_{ref} and the stage's selected tap weight. For example, the current sources in DAC stage 222 and 228 have a value defined by h₁*I_{ref}; likewise the current sources in DAC stage 220 and 230 have a value defined by 1*I_{ref}, i.e., I_{ref}. Furthermore, although not shown, it is understood that each of the remaining DAC stages 220, 222, 224, 228, 230, 232 includes 15 parallel input stages each receiving the differential data bits q3<n>, nq3<n> and generating a current in a manner similar to that shown for DAC stage 226. As described above, the currents generated by the DAC stages are added together by summing block 250 and converted to an analog signal representing the FIR DAC's output voltage.

FIR DAC 200 shown in FIGS. 1 and 4 has the following signal transfer function h(z):

$$h ( z ) = ( 1 - 2 cos \frac{{a}_{1} π}{8} {z}^{- 1} + {z}^{- 2} ) ( 1 - 2 cos \frac{{a}_{2} π}{8} {z}^{- 1} + {z}^{- 2} ) ( 1 - 2 cos \frac{{a}_{3} π}{8} {z}^{- 1} + z - 2 ) = 1 + h 1 z - 1 + h 2 z - 2 + h 3 z - 3 + h 2 z - 4 + h 1 z - 5 + z - 6$$

$$where$$

$${h}_{1} = - 2 cos \frac{{a}_{1} π}{8} - 2 cos \frac{{a}_{2} π}{8} - 2 cos \frac{{a}_{3} π}{8}$$

$${h}_{2} = 3 + 4 cos \frac{{a}_{1} π}{8} cos \frac{{a}_{2} π}{8} + 4 cos \frac{{a}_{2} π}{8} cos \frac{{a}_{3} π}{8} + 4 cos \frac{{a}_{1} π}{8} cos \frac{{a}_{3} π}{8}$$

$${h}_{3} = - 4 cos \frac{{a}_{1} π}{8} - 4 cos \frac{{a}_{2} π}{8} - 4 cos \frac{{a}_{3} π}{8} - 8 cos \frac{{a}_{1} π}{8} cos \frac{{a}_{2} π}{8} cos \frac{{a}_{3} π}{8}$$

The transfer function h(z) has 7 terms signifying the fact that FIR DAC 200 is configured to suppress three odd-harmonically spaced images of the TxRF. Consequently, if the desired signal is centered at the first odd-harmonic image (i.e., n=1), the FIR DAC may be configured to suppress the 3^{rd}, 5^{th} and 7^{th} harmonic images of the TxRF. Likewise, if the desired signal is centered around the third harmonic image (i.e., n=3), the FIR DAC may be configured to suppress the 1^{st}, 5^{th} and 7^{th} harmonic images of the TxRF.

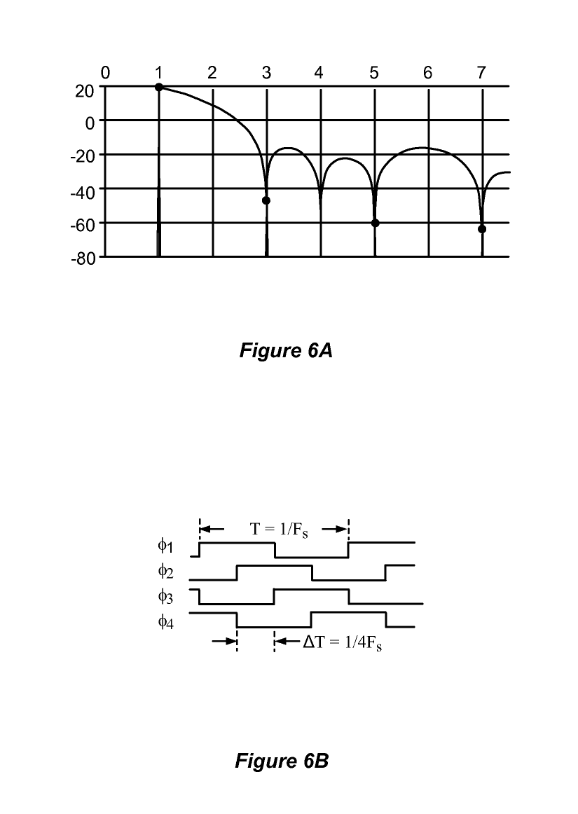

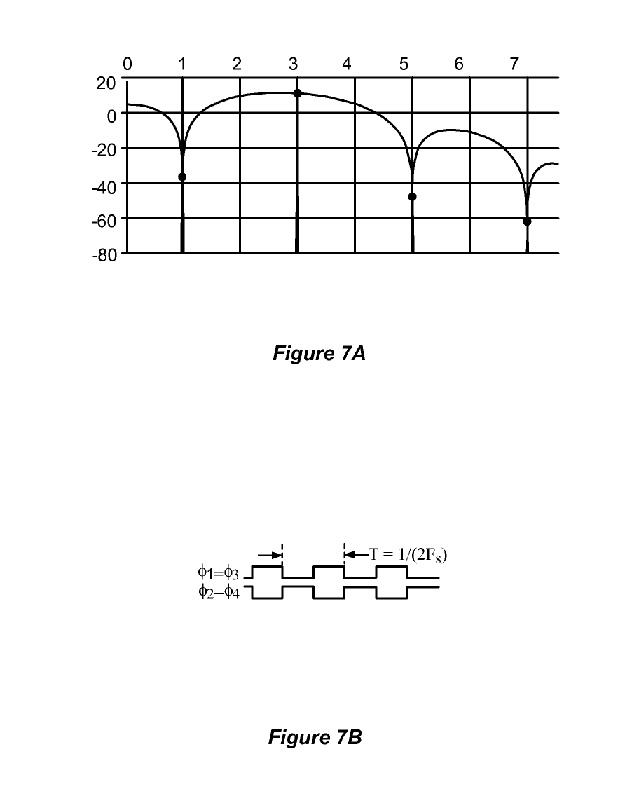

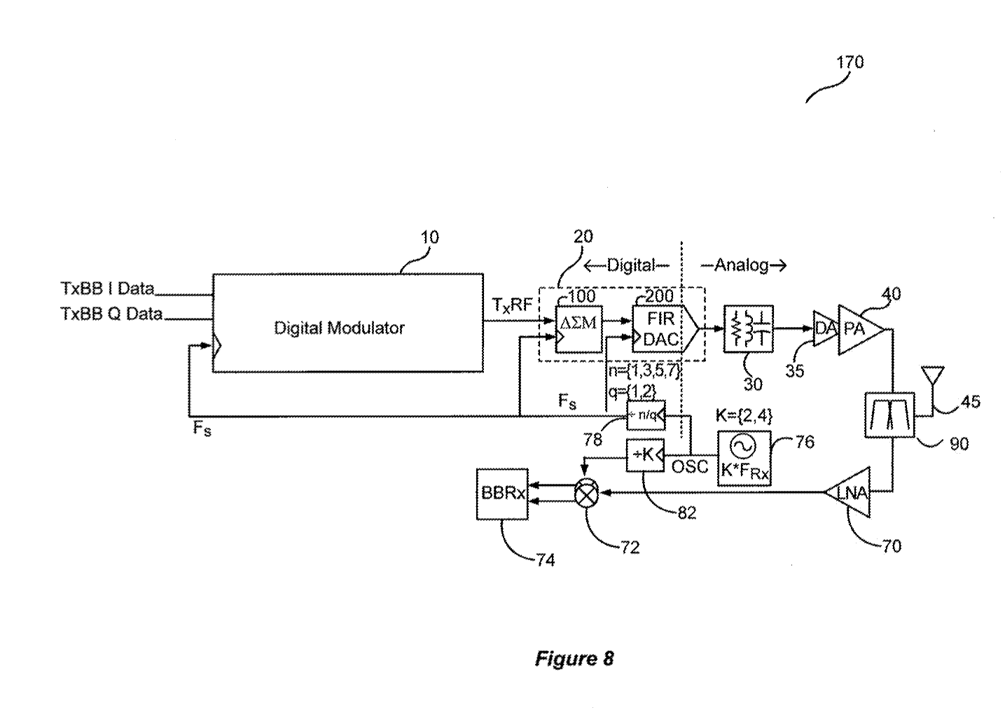

FIG. 6A is the signal transfer function of FIR DAC 200 when n is set to 1. As is seen, the signal centered at the first harmonic (the desired image) has a relatively higher amplitude whereas the signals at 3^{rd}, 5^{th} and 7^{th} harmonic images are substantially attenuated. FIG. 6B shows the relationship between phases φ₁, φ₂, φ₃, φ₄ applied to various delay stages of FIR DAC 200 when the first harmonic is selected as the desired frequency, and the 3^{rd}, 5^{th} and 7^{th} harmonic images are being attenuated. FIG. 7A is the signal transfer function of FIR DAC 200 when n is set to 3. As is seen, the signal centered at the third harmonic (the desired image) has a relatively higher amplitude whereas the signals at 1^{st}, 5^{th} and 7^{th} harmonics are substantially attenuated. FIG. 7B shows the relationship between phases φ₁, φ₂, φ₃, φ₄ applied to various delay stages of FIR DAC 200 when the third harmonic is selected as the desired frequency, and the 1^{st}, 5^{th} and 7^{th} harmonic images are being attenuated.

FIG. 8 is a simplified block diagram of a wireless communication device 170, in accordance with another exemplary embodiment of the present invention. The transmit path of wireless communication device 170 is shown as including, in part, a digital modulator 10, a delta-sigma modulator 100, a FIR DAC 200, load 30, antenna 45, drive amplifier 35, power-amplifier 40, and RF filter 90. The receive path of wireless communication device 170 is shown as including, in part, a low-noise amplifier (LNA) 70, a frequency downconverter 72, and baseband circuitry 74. Wireless communication device 170 is further shown as including a single common local oscillator 76 that generates an oscillating signal OSC used for the receive signal downconversion. Signal OSC is also used to generate sampling clock signal Fₛ that samples the transmit signal.

The common local oscillator 76 has a frequency defined by k*F_{Rx}, where k is an integer, and F_{Rx} is the receive frequency. In the exemplary embodiment of FIG. 8, k is assumed to have a value defined by the set {2, 4}, however, it is understood that k may have any other integer values. Wireless communication device 170 is also shown as including a fractional frequency divider 78 that receives signal OSC and, in response, generates the sampling clock signal Fₛ, applied to digital modulator 10, delta-sigma modulator 100, and FIR DAC 200. Fractional frequency divider 78 is configured to divide the frequency of signal OSC by the ratio n/q, where n is the index of the desired (selected for passing to the output) odd-harmonically spaced sampled signal, as described above, and q is an integer defined by the set {1, 2} in this exemplary embodiment. Divider 82 is shown as dividing the frequency of the oscillating signal OSC by k.

In wireless communication device 170, the Nyquist images of the sampled transmit signal are positioned at n*(F_{Tx}/F_{Rx})*Fₛ. This is in contrast to the Nyquist images for wireless communication device 50 that are positioned at n*Fₛ/4, as described above. Therefore, in order to suppress the undesired images of the transmit signal, the FIR DAC 200 of wireless communication device 170 has a signal transfer function h(z) defined as following:

$$h ( z ) = ( 1 - 2 cos \frac{{a}_{1} π}{8} \frac{{F}_{Tx}}{{F}_{Rx}} {z}^{- 1} + {z}^{- 2} ) ( 1 - 2 cos \frac{{a}_{2} π}{8} \frac{{F}_{Tx}}{{F}_{Rx}} {z}^{- 1} + {z}^{- 2} ) ( 1 - 2 cos \frac{{a}_{3} π}{8} \frac{{F}_{Tx}}{{F}_{Rx}} {z}^{- 1} + z - 2 ) = 1 + h 1 z - 1 + h 2 z - 2 + h 3 z - 3 + h 2 z - 4 + h 1 z - 5 + z - 6$$

with the coefficients as shown below:

$${h}_{1} = - 2 cos \frac{{a}_{1} π}{8} \frac{{F}_{Tx}}{{F}_{Rx}} - 2 cos \frac{{a}_{2} π}{8} \frac{{F}_{Tx}}{{F}_{Rx}} - 2 cos \frac{{a}_{3} π}{8} \frac{{F}_{Tx}}{{F}_{Rx}}$$

$${h}_{2} = 3 + 4 cos \frac{{a}_{1} π}{8} \frac{{F}_{Tx}}{{F}_{Rx}} cos \frac{{a}_{2} π}{8} \frac{{F}_{Tx}}{{F}_{Rx}} + 4 cos \frac{{a}_{2} π}{8} \frac{{F}_{Tx}}{{F}_{Rx}} cos \frac{{a}_{3} π}{8} \frac{{F}_{Tx}}{{F}_{Rx}} + 4 cos \frac{{a}_{1} π}{8} \frac{{F}_{Tx}}{{F}_{Rx}} cos \frac{{a}_{2} π}{8} \frac{{F}_{Tx}}{{F}_{Rx}}$$

$${h}_{3} = - 4 cos \frac{{a}_{1} π}{8} \frac{{F}_{Tx}}{{F}_{Rx}} - 4 cos \frac{{a}_{2} π}{8} \frac{{F}_{Tx}}{{F}_{Rx}} - 4 cos \frac{{a}_{3} π}{8} \frac{{F}_{Tx}}{{F}_{Rx}} - 8 cos \frac{{a}_{2} π}{8} \frac{{F}_{Tx}}{{F}_{Rx}} cos \frac{{a}_{3} π}{8} \frac{{F}_{Tx}}{{F}_{Rx}}$$

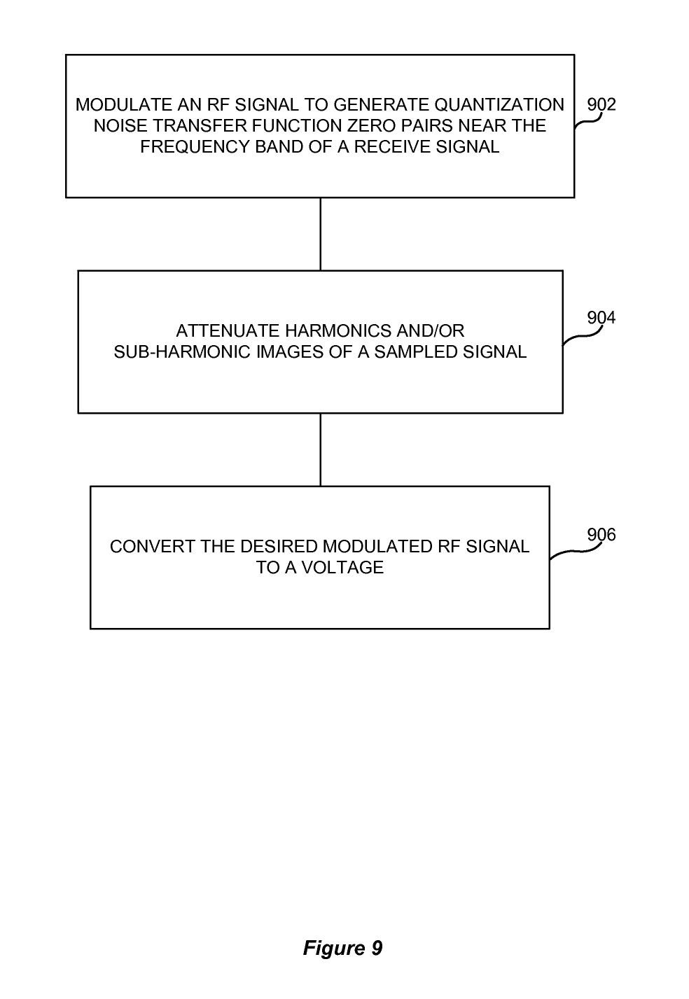

FIG. 9 shows a flowchart 900 for transmitting an RF signal, in accordance with one embodiment of the present invention. Before transmission, the RF signal is modulated 902 to generate a multitude of quantization noise transfer function zero pairs positioned substantially near the frequency band of the receive signal. A multitude of the harmonics of the sampled signal are then suppressed 904 in the modulated signal. The desired modulated signal is converted 906 to an analog voltage and or current and subsequently delivered to an antenna for transmission.

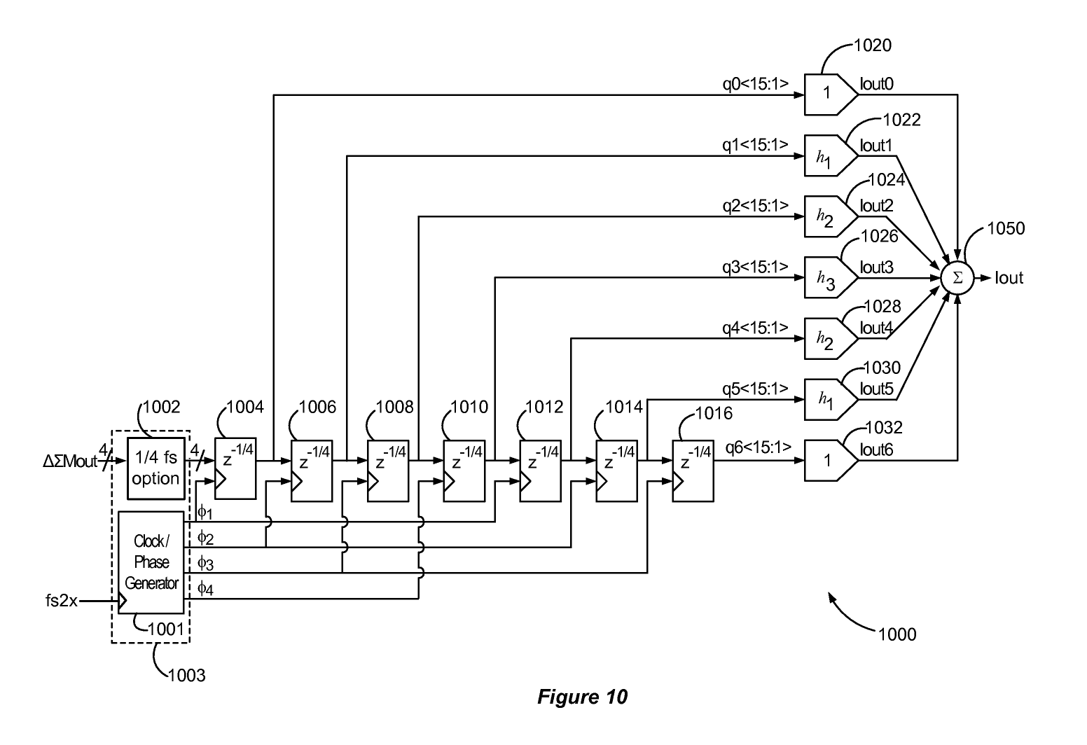

FIG. 10 illustrates a schematic diagram for an alternate 7-tap, 16-level FIR DAC using a combined clock phase generator. The difference between the FIR DAC illustrated in FIG. 10 (e.g., second embodiment) and the FIR DAC illustrated in FIG. 4 (e.g., first embodiment) is that the second embodiment uses a combined Fₛ/4 and 3Fₛ/4 clock phase generator 1003 to generate clocks for both the Fₓ/4 and 3Fₛ/4 modes of operation. In addition, the second embodiment places thermo decoders between outputs of the register delays and the DAC stages, followed by another set of register delays for re-timing to the clock phases. As a result, the FIR DAC in the second embodiment achieves better timing accuracy and consumes less power compared to the FIR DAC in the first embodiment. The FIR DAC in the second embodiment enables a single circuit design to implement both Fₛ/4 and 3Fₛ/4 frequency plans (e.g., both FIGS. 6A and 7A) with a programming option.

As illustrated in FIG. 10, the FIR DAC 1000 includes a combined clock phase generator 1003, delay stages 1004, 1006, 1008, 1010, 1012, 1014, and 1016, current steering DAC stages 1020, 1022, 1024, 1026, 1028, 1030, and 1032, and a summing network 1050. The outputs of the delay stages 1004, 1006, 1008, 1010, 1012, 1014, and 1016 are shown as being applied to current steering DAC stages 1020, 1022, 1024, 1026, 1028, 1030 and 1032 which respectively receive tap weights of 1, h₁, h₂, h₃, h₂, h₁, and 1. The currents generated by the seven stages, namely currents Iₒᵤₜ₀, Iₒᵤₜ₁, Iₒᵤₜ₂, Iₒᵤₜ₃, Iₒᵤₜ₄, Iₒᵤₜ₅ and Iₒᵤₜ₆ are summed by summing network 1050 and subsequently converted to an analog voltage forming the output of the FIR DAC 1000. As with summing network 250, summing network 1050 can be as simple as a wired connection of differential DAC stages 1020, 1022, 1024, 1026, 1028, 1030 and 1032 outputs.

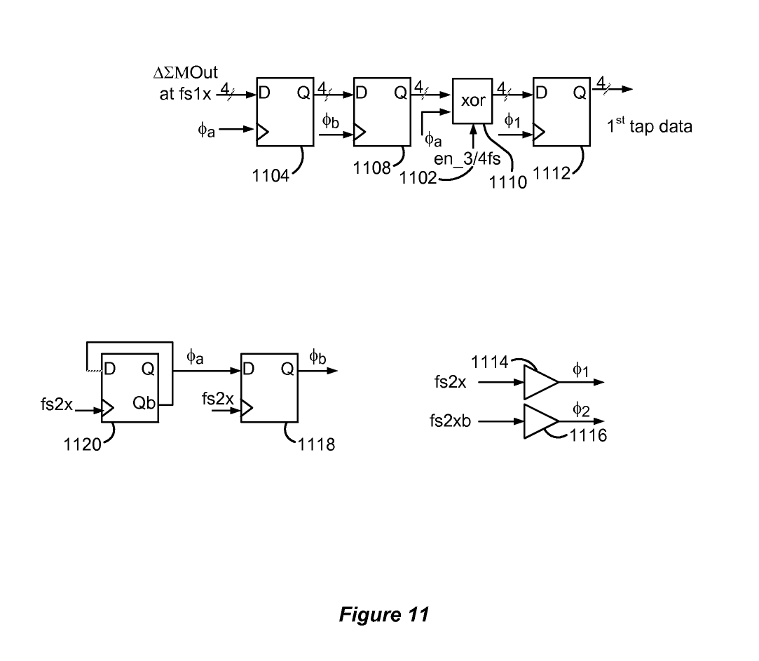

FIG. 11 illustrates the combined clock phase generator 1003 for Fₛ/4 and 3Fₛ/4 modes (as illustrated in FIG. 10), in accordance with one embodiment of the present disclosure. As illustrated, the combined clock phase generator 1003 may include registers 1104, 1108, 1112, 1118 and 1120, XOR 1110, gain units 1114 and 1116, and the like. The combined clock phase generator 1003 receives the output of the Delta-Sigma modulator and the Fs2x signal as inputs and generates a 4-bit first tap data and two phases of the clock signal (e.g., φ₁ and φ₂) as outputs. As illustrated, φ₁ and φ₂ are generated by passing the fs2x and its invert signal (e.g., fs2xb) through gain units 1114 and 1116, respectively. It should be noted that the en_{—}¾fs is passed through a logical AND operation with the φₐ signal before being input to the XOR gate 1110 (not shown).

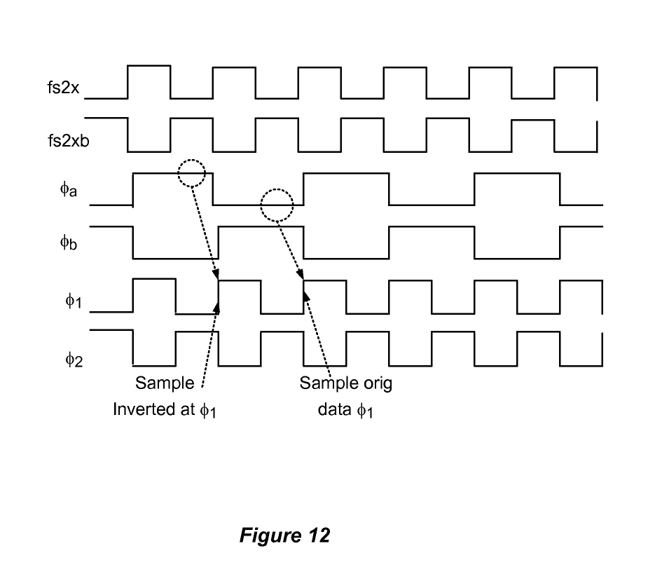

FIG. 12 shows the 3Fₛ/4 waveforms that are generated in the combined clock phase generator 1003 when the en_{—}¾fs signal 1102 is asserted. In this Figure, waveforms for the fs2x (e.g., which has a frequency equal to 2×Fₛ), fs2xb, internal signals φ₁ and φ₂ and the output clock signals φ₁ and φ₂ are illustrated.

The combined clock phase generator 1003 converts the 4-bit output of the Delta-Sigma modulator to 4-bit first tap data that are delivered to each of the register delay stages 1004, 1006, 1008, 1010, 1012, 1014, 1016 (e.g., z^{-1/4}), each of which is shown as including a register having a clock signal that receives a different one of two different clock phases φ₁, φ₂. As described above, the output of each delay stage is received by an associated DAC stage. For example, the output of delay stage 1004 is received by associated DAC stage 1020. Likewise, the output of delay stage 1008 is received by associated DAC stage 1024; and the output of delay stag 1016 is received by associated DAC stage 1032.

Similar to the first embodiment, each of DAC stages 1020, 1022, 1024, 1026, 1028, 1030, and 1032 in the second embodiment is adapted to generate a current defined by the data it receives from its associated delay stage and its selected tap weight. For example, the output of DAC stage 1020 is defined by the 15-bit data it receives from its associated delay stage 1004 and its tap weight which is selected to be 1. Likewise the output of DAC stage 1022 is defined by the 15-bit data it receives from its associated delay stage 1006 and its selected tap weight h₁; and the output of DAC stage 1024 is defined by the 15-bit data it receives from its associated delay stage 1008 and its selected tap weight h₂.

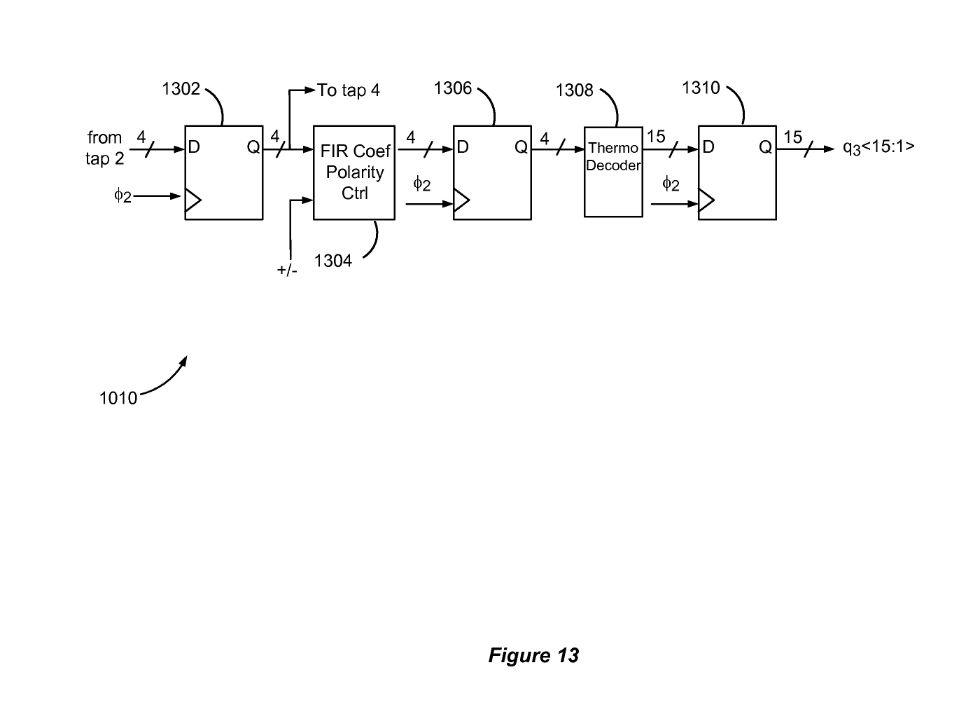

As shown in FIG. 10, the z^{-1/4} tap delays are clocked at 2×Fₛ by either φ₁ or φ₂ as in the original 3Fₛ/4 mode, but the data are modulated per the en_{—}¾fs signal 1102. FIG. 13 shows tap clock and data path of one of the z^{-1/4} tap delays (e.g., the tap delay 1010) in FIG. 10 in more detail. As illustrated, the tap delay 1010 may include registers 1302, 1306 and 1310, a FIR coefficient polarity control unit 1304 and a thermo decoder 1308. As described earlier, the thermo decoder 1308 is placed inside the register delay 1010, followed by another set of register delays for re-timing the clock phases.

The second embodiment shown in FIG. 10 consumes less power compared to the first embodiment shown in FIG. 4, because placing the 4-to-15 thermo decoders after the tap delays allows the tap data path to be 4-bits wide, compared to 15-bits used in the embodiment shown in FIG. 4.

The above embodiments of the present invention are illustrative and not limitative. The embodiments of the present invention are not limited by the noise transfer function of the Delta-Sigma modulator, by the number of stages (number of zero pairs) of the Delta-Sigma modulator, or by the bit-width of the modulator. The above embodiments of the present invention are not limited by the signal transfer functions or the number of harmonics that the DAC may be configured to suppress. The above embodiments of the present invention are not limited by any particular relationship between the transmit signal frequency and the sampling clock frequency.

What is claimed is:

1. A communication device comprising a transmitter and a receiver, said transmitter comprising:
a delta-sigma modulator receiving an RF signal and characterized by a noise transfer function having a plurality of quantization noise transfer function zeroes positioned substantially near a frequency band of a receive signal; and
a multi-phase digital-to-analog (DAC) converter configured to convert an output signal of the delta-sigma modulator to an analog signal, said DAC characterized by a transfer function operative to pass a selected one of a plurality of images of a sampled signal and attenuate a subset of the plurality of images of the sampled signal, said subset not to include the selected image of the sampled signal, said sampled signal being sampled by a sampling clock signal and upconverted to the RF signal.

2. The communication device of claim 1 wherein said RF signal is a digital RF signal.

3. The communication device of claim 1 wherein said DAC comprises a plurality of stages, said plurality of stages being determined by the number of images of the sampled signal that are to be attenuated.

4. The communication device of claim 1 wherein said transmitter is configured to transmit at a frequency defined by an odd multiple of a fraction of the sampling clock signal frequency.

5. The communication device of claim 4 wherein said fraction is one-fourth.

6. The communication device of claim 1 wherein said baseband signal comprises an in-band signal component and a quadrature-phase signal component.

7. The communication device of claim 1 wherein said subset of the plurality of images of the sampled signal includes the third, fifth, and seventh images of the sampled signal.

8. The communication device of claim 4 wherein said DAC is a current steering DAC.

9. The communication device of claim 8 wherein each stage of the DAC comprises a current source providing a current having a value defined by a tap weight associated with the stage.

10. The communication device of claim 9 wherein said fraction of the sampling frequency defines a number of phases of the sampling clock signal received by the DAC.

11. The communication device of claim 1 further comprising:
a load receiving an output of said DAC.

12. The communication device of claim 11 further comprising:
an amplifier receiving an output of said load.

13. The communication device of claim 1 wherein said delta-sigma modulator comprises a plurality of stages each associated with a different one of the plurality of quantization noise transfer function zeroes.

14. The communication device of claim 13 wherein each stage of said delta-sigma modulator receives at least three tap coefficients.

15. The communication device of claim 1 wherein said receiver is configured to receive at one or more frequencies defined by one or more odd multiples of a fraction of the sampling clock signal frequency.

16. The communication device of claim 15 wherein said fraction is ¼.

17. The communication device of claim 1 wherein said communication device further comprises:
a local oscillator shared by the transmitter and the receiver.

18. The communication device of claim 17 wherein said shared LO has a frequency that is a multiple of the receive frequency.

19. The communication device of claim 1 wherein the subset of the plurality of images being attenuated is defined by odd multiples of a fraction of the sampling clock signal frequency.

20. The communication device of claim 19 wherein said fraction is defined by a ratio of the transmit frequency to the receive frequency.

21. A method of wireless communication comprising:
modulating the RF signal to generate a plurality of quantization noise transfer function zeroes positioned substantially near a frequency band of a receive signal;
attenuating a plurality of images of a sampled baseband transmit signal upconverted to the RF signal;
converting the modulated RF signal to an analog signal; and
transmitting the analog signal.

22. The method of claim 21 wherein said RF signal is a digital RF signal.

23. The method of claim 21 further comprising:
transmitting the RF signal at a frequency defined by an odd multiple of a fraction of a sampling clock signal frequency sampling the baseband transmit signal.

24. The method of claim 23 wherein said fraction is one-fourth.

25. The method of claim 21 wherein said baseband frequency signal comprises an in-band signal component and a quadrature-phase signal component.

26. The method of claim 21 wherein the plurality of images of the sampled signal includes the third, fifth, and seventh images of the sampled signal.

27. The method of claim 23 wherein said converting the modulated RF signal to the analog signal is performed using a current steering DAC.

28. The method of claim 27 wherein said current steering DAC includes a number of stages that is one higher than twice a number of the plurality of attenuated images of the sampled signal.

29. The method of claim 28 wherein each stage of the current steering DAC comprises a current source providing a current having a value defined by a tap weight associated with the stage.

30. The method of claim 29 wherein said fraction of the sampling clock signal frequency defines a number of phases of the clock signal received by the DAC.

31. The method of claim 21 further comprising:
applying an output of said DAC to a load.

32. The method of claim 31 further comprising:
applying an output of said load to an amplifier.

33. The method of claim 21 further comprising:
modulating the RF signal via a plurality of stages each of which is associated with a different one of the plurality of quantization noise transfer function zeroes.

34. The method of claim 33 further comprising:
applying at least three tap coefficients to each of the plurality of stages.

35. The method of claim 21 further comprising:
receiving a second RF signal at one or more frequencies defined one or more odd multiples of a fraction of a sampling clock signal frequency used to sample the baseband transmit signal.

36. The method of claim 35 wherein said fraction is ¼.

37. The method of claim 21 further comprising:
sharing a local oscillator between a transmitter transmitting the RF signal and a receiver receiving the second RF signal.

38. The method of claim 37 wherein said shared LO has a frequency that is a multiple of the receive frequency.

39. The method of claim 21 wherein the subset of the plurality of images being attenuated is defined by odd multiples of a fraction of a sampling clock signal frequency.

40. The method of claim 39 wherein said fraction is defined by a ratio of the transmit frequency to the receive frequency.

41. A wireless communication device comprising a transmitter, said transmitter comprising:
means for modulating an RF signal to generate a plurality of quantization noise transfer function zeroes positioned substantially near a frequency band of a receive signal;
means for attenuating a plurality of images of a sampled baseband transmit signal upconverted to the RF signal;
means for converting an output of the attenuating means to an analog signal; and
means for transmitting the analog signal.

42. The wireless communication device of claim 41 wherein said RF signal is a digital RF signal.

43. The wireless communication device of claim 41 further comprising:
means for transmitting the RF signal at a frequency defined by an odd multiple of a fraction of a sampling clock signal frequency used to sample the transmit signal.

44. The wireless communication device of claim 43 wherein said fraction is one-fourth.

45. The wireless communication device of claim 41 wherein said baseband frequency signal comprises an in-band signal component and a quadrature-phase signal component.

46. The wireless communication device of claim 41 wherein the plurality of images of the samples signal includes the third, fifth, and seventh images of the sampled signal.

47. The wireless communication device of claim 43 wherein the means for converting the modulated RF signal to the analog signal is a current steering DAC.

48. The wireless communication device of claim 47 wherein said current steering DAC includes a number of stages that is one higher than twice a number of the plurality of attenuated images of the sampled signal.

49. The wireless communication device of claim 48 wherein each stage of the current steering DAC comprises a current source providing a current having a value defined by a tap weight associated with the stage.

50. The wireless communication device of claim 49 wherein said fraction of the sampling clock signal frequency defines a number of phases of the sampling clock signal received by the DAC.

51. The wireless communication device of claim 41 further comprising:
means for applying an output of said DAC to a load.

52. The wireless communication device of claim 51 further comprising:
means for applying an output of said load to an amplifier.

53. The wireless communication device of claim 41 further comprising:
means for modulating the RF signal via a plurality of stages each of which is associated with a different one of the plurality of zeroes.

54. The wireless communication device of claim 53 further comprising:
means for applying at least three tap coefficients to each of the plurality of stages.

55. The wireless communication device of claim 41 further comprising:
means for receiving a second RF signal at one or more frequencies defined by one or more odd multiples of a fraction of a sampling clock signal frequency used to sample the transmit signal.

56. The wireless communication device of claim 55 wherein said fraction is ¼.

57. The wireless communication device of claim 55 further comprising:
means for sharing a local oscillator between the transmitter and the means for receiving.

58. The wireless communication device of claim 57 wherein said shared LO has a frequency that is a multiple of the receive frequency.

59. The wireless communication device of claim 41 wherein the subset of the plurality of images being attenuated is defined by odd multiples of a fraction of the sampling clock signal frequency.

60. The wireless communication device of claim 59 wherein said fraction is defined by a ratio of the transmit frequency to the receive frequency.
